(19) United States
(12) Patent Application Publication
(10) Pub. No.: US 2025/0347505 A1
(43) Pub. Date: Nov. 13, 2025

(54) DETECTION DEVICE

(71) Applicant: Japan Display Inc., Tokyo (JP)

(72) Inventor: Takayuki NAKANISHI, Tokyo (JP)

(21) Appl. No.: 19/192,966

(22) Filed: Apr. 29, 2025

(30) Foreign Application Priority Data
May 8, 2024 (JP) 2024-076106

(51) Int. Cl. G01B 7/008; G01D 5/24

(52) U.S. Cl. CPC G01B 7/008; G01D 5/24

(57) ABSTRACT

According to an aspect, a detection device includes: a detection region provided with a plurality of electrodes; a front surface covering member made of hygroscopic non-conductive material and covering the detection region; and a detector configured to detect an object to be detected in proximity to the detection region with the front surface covering member interposed between the object to be detected and the detection region. The detector acquires an adjustment coefficient for adjusting a signal value acquired when detecting the object to be detected, based on a correspondence between a signal value acquired in a non-detection operation in which the object to be detected is not detected and a moisture content of the front surface covering member.

### CROSS-REFERENCE TO RELATED APPLICATION

This application claims the benefit of priority from Japanese Patent Application No. 2024-076106 filed on May 8, 2024, the entire contents of which are incorporated herein by reference.

### BACKGROUND

### 1. Technical Field

What is disclosed herein relates to a detection device.

### 2. Description of the Related Art

In recent years, widely known are detection devices, what are called touch panels, capable of detecting an external proximity object. There have been disclosed front surface covering members for such touch panels made of naturally derived wood, natural fibers, natural leather or natural stones, or synthetic fibers, synthetic leather, artificial stones or the like produced to imitate the natural appearance and feel (refer to WO 2019/082399, for example).

In what is called a capacitive touch panel, if a front surface covering member made of hygroscopic non-conductive material is provided on the front surface of the touch panel, the permittivity of the front surface covering member may possibly change due to a change in humidity, resulting in deterioration in detection accuracy.

For the foregoing reasons, there is a need for a detection device that can suppress deterioration in detection accuracy.

### SUMMARY

According to an aspect, a detection device includes: a detection region provided with a plurality of electrodes; a front surface covering member made of hygroscopic non-conductive material and covering the detection region; and a detector configured to detect an object to be detected in proximity to the detection region with the front surface covering member interposed between the object to be detected and the detection region. The detector acquires an adjustment coefficient for adjusting a signal value acquired when detecting the object to be detected, based on a correspondence between a signal value acquired in a non-detection operation in which the object to be detected is not detected and a moisture content of the front surface covering member.

### BRIEF DESCRIPTION OF THE DRAWINGS

FIG. 1 is a plan view of a schematic configuration of a detection device according to a first embodiment;

FIG. 2 is a schematic of a sectional configuration of a sensor of the detection device according to the first embodiment;

FIG. 3 is a block diagram of an exemplary configuration of a detector of the detection device according to the first embodiment;

FIG. 4A is a schematic of the relation between the position of an object to be detected in a space on a detection region and the positions of respective electrodes;

FIG. 4B is a schematic of the spatial coordinates of the object to be detected in the space on the detection region;

FIG. 5 is a diagram of an example of the coupling configuration between the sensor and the detector of the detection device according to the first embodiment;

FIG. 6 is a flowchart of an example of specific operations and processing in the detection device according to the first embodiment;

FIG. 7 is a sub-flowchart of an example of an adjustment coefficient setting process in the detection device according to the first embodiment;

FIG. 8 is a conceptual diagram illustrating an adjustment coefficient setting operation of the detection device according to the first embodiment;

FIG. 9 is a graph indicating an example of the correspondence between the signal value acquired in the adjustment coefficient setting operation and the adjustment coefficient;

FIG. 10 is a sub-flowchart of an example of the adjustment coefficient setting process according to a modification of the first embodiment;

FIG. 11A is a conceptual diagram illustrating the adjustment coefficient setting operation according to the modification of the first embodiment;

FIG. 11B is a conceptual diagram illustrating the adjustment coefficient setting operation according to the modification of the first embodiment;

FIG. 12 is a plan view of a first example of the electrode configuration in the sensor of the detection device according to a second embodiment;

FIG. 13 is a schematic of a first example of a sectional configuration of the sensor of the detection device according to the second embodiment;

FIG. 14 is a plan view of a second example of the electrode configuration in the sensor of the detection device according to the second embodiment;

FIG. 15 is a schematic of a second example of a sectional configuration of the sensor of the detection device according to the second embodiment;

FIG. 16 is a sub-flowchart of an example of the adjustment coefficient setting process in the detection device according to the second embodiment; and

FIG. 17 is a conceptual diagram illustrating the adjustment coefficient setting operation of the detection device according to the second embodiment.

### DETAILED DESCRIPTION

Exemplary aspects (embodiments) to embody the present disclosure are described below in greater detail with reference to the accompanying drawings. The contents described in the embodiments below are not intended to limit the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present disclosure and easily conceivable by those skilled in the art naturally fall within the scope of the present disclosure. To make the explanation more specific, the drawings may possibly illustrate the width, the thickness, the shape, and other elements of each component more schematically than the actual aspect. These elements, however, are given by way of example only and are not intended to limit interpretation of the present disclosure. In the present specification and the drawings, components similar to those previously described with reference to previous drawings are denoted by the same reference numerals, and detailed explanation thereof may be omitted as appropriate.

### First Embodiment

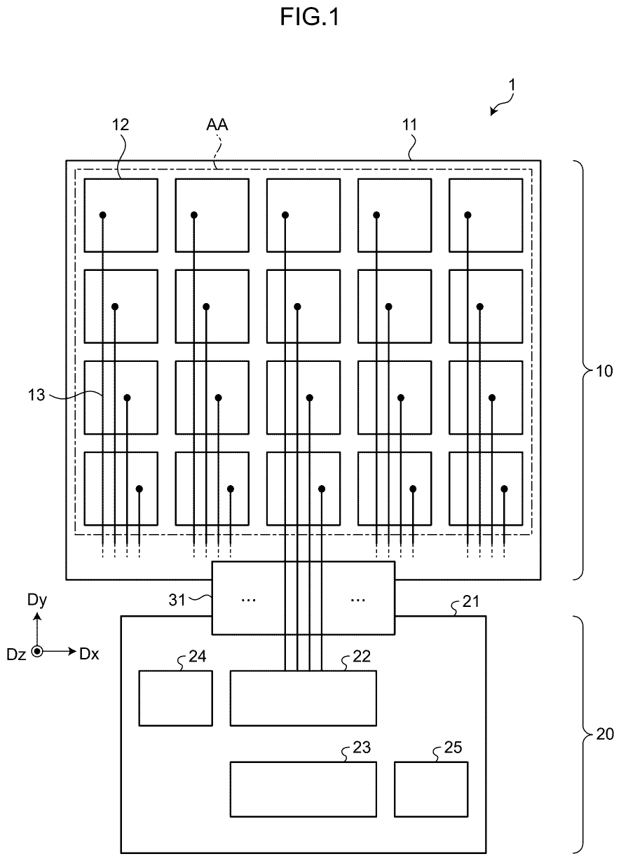

FIG. 1 is a plan view of a schematic configuration of a detection device according to a first embodiment. As illustrated in FIG. 1, a detection device 1 includes a sensor 10 and a detector 20.

The sensor 10 includes a sensor substrate 11, a plurality of electrodes 12 provided in a detection region AA of the sensor substrate 11, and wiring 13 extending from the electrodes 12. The detector 20 includes a control substrate 21, a detection circuit 22, a processing circuit 23, a power supply circuit 24, and an interface circuit 25.

The detection region AA of the sensor substrate 11 is a region provided with a plurality of electrodes 12 arrayed in a matrix (row-column configuration) in a Dx direction (first direction) and a Dy direction (second direction). The sensor substrate 11 is a rigid substrate or flexible printed circuits (FPC) with flexibility, for example.

In the present disclosure, the Dx direction and the Dy direction are orthogonal in the detection region AA of the sensor substrate 11. In the present disclosure, the direction orthogonal to the Dx direction and the Dy direction is referred to as Dz direction (third direction).

While FIG. 1 illustrates an example where 5×4(=20) electrodes 12 with five electrodes 12 in the Dx direction and four electrodes 12 in the Dy direction are provided, the number of electrodes 12 provided to the detection region AA of the sensor substrate 11 is not limited thereto.

The sensor substrate 11 is electrically coupled to the control substrate 21 via a wiring substrate 31. The wiring substrate 31 is flexible printed circuits, for example. Each electrode 12 of the sensor 10 is coupled to the detection circuit 22 of the detector 20 via the wiring substrate 31.

The control substrate 21 is provided with the detection circuit 22, the processing circuit 23, the power supply circuit 24, and the interface circuit 25. The control substrate 21 is a rigid board, for example.

The detection circuit 22 generates a detection value of each electrode 12 based on detection signals of the electrode 12 output from the sensor substrate 11. The detection circuit 22 is an analog front-end (AFE) IC, for example.

The processing circuit 23 generates the spatial coordinates indicating the position of an object to be detected (e.g., operator's finger) on or above the detection region AA based on the detection values of the electrodes 12 that are output from the detection circuit 22. The processing circuit 23 may be a programmable logic device (PLD), such as a field programmable gate array (FPGA), or a micro control unit (MCU), for example.

The power supply circuit 24 is a circuit that supplies power to the detection circuit 22 and the processing circuit 23.

The interface circuit 25 is a USB controller IC, for example, and is a circuit that controls communications between the processing circuit 23 and a host controller of a host device (not illustrated).

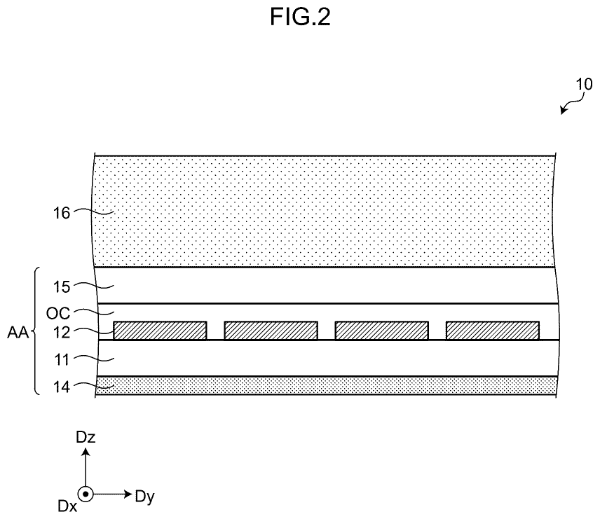

FIG. 2 is a schematic of a sectional configuration of the sensor of the detection device according to the first embodiment. The sensor 10 includes the sensor substrate 11, the electrodes 12, a shield electrode 14, and an electrode protection layer 15. The electrode protection layer 15 is a cover glass, for example.

In the sensor 10, the electrode protection layer 15 is provided facing one surface of the sensor substrate 11 on which a plurality of electrodes 12 are provided, with an adhesive layer OC interposed between the one surface of the sensor substrate 11 and the electrode protection layer 15. The shield electrode 14 is provided on the other surface of the sensor substrate 11. In the sensor 10, the layers of the shield electrode 14, the sensor substrate 11, the electrodes 12, and the electrode protection layer 15 are stacked in this order to form the detection region AA.

The surface layer of the electrode protection layer 15 according to the present disclosure is provided with a hygroscopic front surface covering member 16. In other words, the detection region AA of the sensor 10 is covered by the front surface covering member 16.

The front surface covering member 16 is a member made of hygroscopic non-conductive material. Specifically, examples of the material of the front surface covering member 16 include, but are not limited to, naturally derived wood, natural fibers, and natural leather, or synthetic fibers and synthetic leather produced to imitate the natural appearance and feel, etc. Alternatively, the front surface covering member 16 may be a member made of, for example, diatomaceous earth, plaster, or plasterboard.

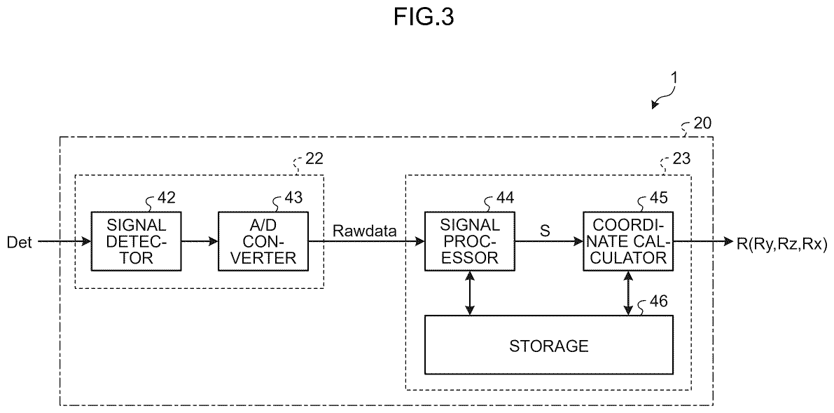

FIG. 3 is a block diagram of an exemplary configuration of the detector of the detection device according to the first embodiment.

As illustrated in FIG. 3, the detector 20 includes a signal detector 42, an analog-to-digital (A/D) converter 43, a signal processor 44, a coordinate calculator 45, and a storage 46. The signal detector 42 and the A/D converter 43 are included in the detection circuit 22. The signal processor 44, the coordinate calculator 45, and the storage 46 are included in the processing circuit 23.

The signal detector 42 generates a detection value Rawdata of each electrode 12 based on a detection signal Det of the electrode 12 output from the sensor substrate 11. The A/D converter 43 converts the detection value of each electrode 12 into a digital signal by sampling the detection value.

The signal processor 44 performs various processes, such as baseline processing and linear transformation, on the detection value Rawdata of each electrode 12 and outputs the processing result as a detection value S of the electrode 12.

The coordinate calculator 45 extracts the spatial coordinates of the position of the object to be detected, based on the detection values S of the electrodes 12 in the detection region AA.

The storage 46 stores therein various parameters, tables, and the like used in the processing performed by the signal processor 44 and the coordinate calculator 45. The storage 46 also has a function of storing therein intermediate data or the like in the processing performed by the signal processor 44 and the coordinate calculator 45.

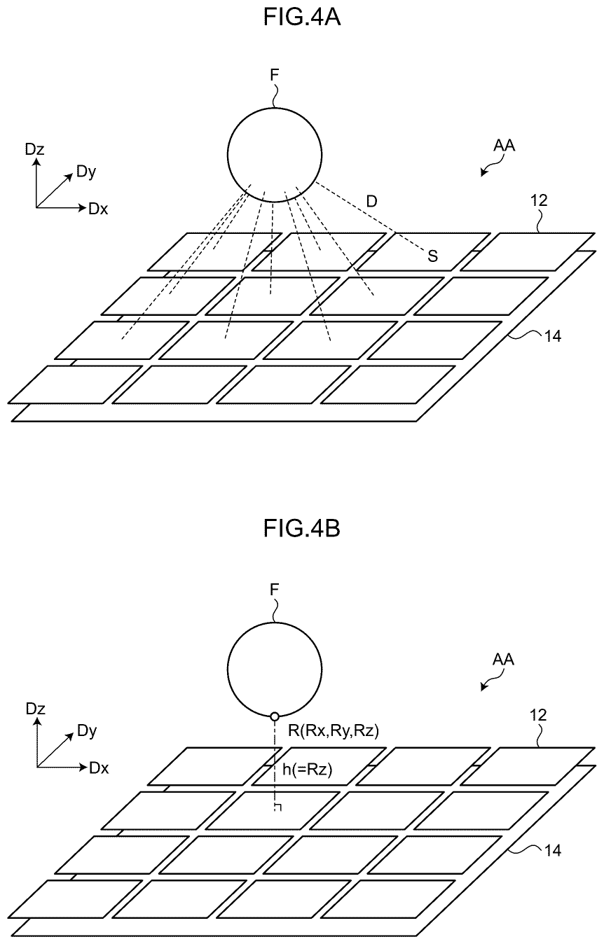

FIG. 4A is a schematic of the relation between the position of the object to be detected in a space on the detection region and the positions of the respective electrodes. FIG. 4B is a schematic of the spatial coordinates of the object to be detected in the space on the detection region. FIGS. 4A and 4B illustrate an example where an object to be detected F is in the space on the detection region AA.

Each electrode 12 in the detection region AA generates capacitance corresponding to a distance D between the object to be detected F in the space on the detection region AA and the electrode 12, and the detection value Rawdata corresponding to the capacitance is acquired by the detection circuit 22. The detection value Rawdata acquired by the detection circuit 22 is subjected to various processes, such as baseline processing and linear transformation, by the signal processor 44. As a result, the detection value S of each electrode 12 is generated.

The coordinate calculator 45 calculates the spatial coordinates R (Rx, Ry, Rz) indicating the position of the object to be detected F in the space on the detection region AA illustrated in FIG. 4B based on the detection values S of the electrodes 12 generated by the signal processor 44.

In the present disclosure, the spatial coordinates R (Rx, Ry, Rz) include data Rx indicating the position in the Dx direction (first direction) in the detection region AA, data Ry indicating the position in the Dy direction (second direction) in the detection region AA, and data Rz indicating the position in the Dz direction (third direction) orthogonal to the Dx direction and the Dy direction.

The spatial coordinates R (Rx, Ry, Rz) indicate the position of the object to be detected F with respect to the surface of the electrode protection layer 15 serving as a reference surface. In other words, the object to be detected F according to the present disclosure is present at a position on the detection region AA with the front surface covering member 16 interposed therebetween.

As described above, the detection device 1 according to the present disclosure is configured to detect the spatial coordinates of the position of the object to be detected F on or above the detection region AA by detecting the capacitance generated on the electrodes 12. To detect the object to be detected F at a position away from the detection region AA in the Dz direction, it is necessary to enhance the sensitivity by increasing the size of each electrode 12 compared with a configuration that detects the plane coordinates of the contact position of the object to be detected F with the detection surface. Typically, the size of each electrode 12 is preferably approximately 20 mm×20 mm to 40 mm×40 mm, for example, and is specifically approximately 30 mm×30 mm.

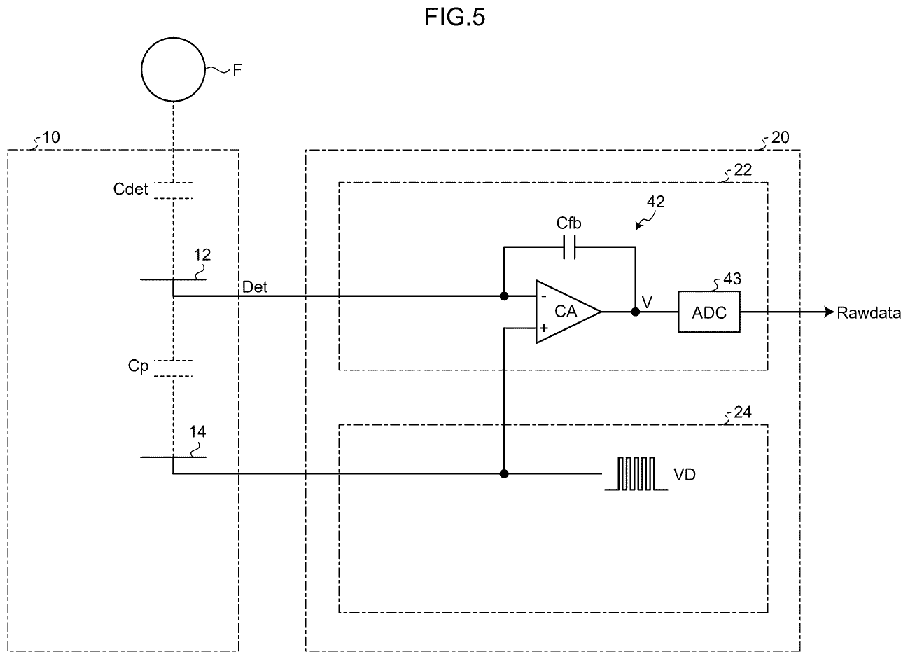

The following describes the baseline processing performed by the signal processor 44. FIG. 5 is a diagram of an example of the coupling configuration between the sensor and the detector of the detection device according to the first embodiment.

As illustrated in FIG. 5, the signal detector 42 of the detection circuit 22 includes a differential amplifier circuit CA as a main component. The detection device 1 according to the present disclosure is a self-capacitance detection device that generates an electric field by the plurality of electrodes 12 to detect the object to be detected F.

The non-inverting input terminal of the differential amplifier circuit CA is supplied with drive signals VD for detection from the power supply circuit 24. The drive signal VD is a square wave signal that repeats a high potential and a low potential in a predetermined cycle.

The inverting input terminal of the differential amplifier circuit CA is coupled to the electrode 12 provided in the detection region AA. Negative feedback capacitor Cfb is provided between the inverting input terminal and the output terminal of the differential amplifier circuit CA. The differential amplifier circuit CA functions as an integration circuit by the drive signals VD being supplied to the non-inverting input terminal.

The shield electrode 14 is supplied with the drive signals VD from the power supply circuit 24.

The detection value Rawdata acquired in a detection operation is expressed by the following Expression (1), where S(Cdet) is a component caused by capacitance Cdet generated between the object to be detected F and the electrode 12, and S(Cp) is a component caused by parasitic capacitance Cp.

Rawdata=S(Cdet)+S(Cp) (1)

The signal processor 44 determines the detection value, which has been acquired in advance when the object to be detected F is not present in an object detectable space where an object can be detected on/above the detection region AA, to be a baseline BL(=S(Cp)). The signal processor 44 subtracts the baseline BL from the detection value Rawdata of each electrode 12 acquired in the normal detection operation, thereby acquiring the component S(Cdet) from which the component (S(Cp)) caused by the parasitic capacitance Cp is removed, as a signal value Signal of the electrode 12.

As described above, the detection device 1 according to the present disclosure is provided with the front surface covering member 16 covering the detection region AA on the surface layer of the electrode protection layer 15 of the sensor 10. The permittivity of the front surface covering member 16 made of hygroscopic non-conductive material changes with a change in humidity. Therefore, this configuration may possibly deteriorate the accuracy of detecting the object to be detected F at a position on the detection region AA with the front surface covering member 16 interposed therebetween.

In the detection device 1 according to the present disclosure, the signal processor 44 adjusts the detection value acquired when performing a detection operation to detect the object to be detected F, based on the detection value acquired in a non-detection operation when the object to be detected F is not detected, apart from the baseline processing described above. The following describes specific operations in the detection device 1 according to the first embodiment.

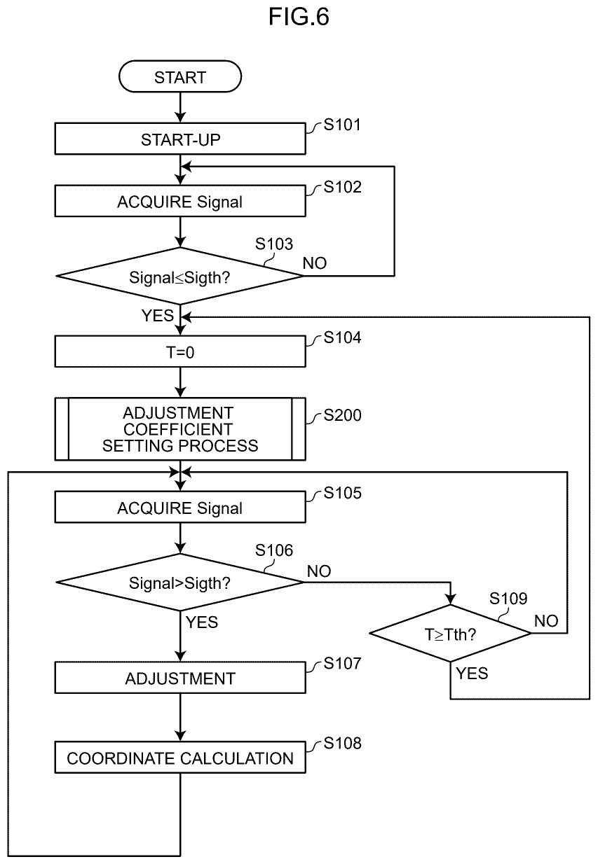

FIG. 6 is a flowchart of an example of specific operations and processing in the detection device according to the first embodiment.

When the detection device 1 is started (Step S101), the signal processor 44 of the detector 20 acquires the signal value Signal of each electrode 12 (Step S102) and performs comparison arithmetic processing between the acquired signal value Signal of each electrode 12 and an adjustment coefficient setting threshold Sigth. Specifically, the signal processor 44 determines whether the signal value Signal of each electrode 12 acquired at Step S102 is equal to or smaller than the adjustment coefficient setting threshold Sigth (Step S103).

The adjustment coefficient setting threshold Sigth is a threshold for determining whether to perform an adjustment coefficient setting process (Step S200), which will be described later. The adjustment coefficient setting process (Step S200), which will be described later, needs to be performed when the object to be detected F is not present in the object detectable space on/above the detection region AA. If the signal value Signal of each electrode 12 acquired at Step S102 is equal to or smaller than the adjustment coefficient setting threshold Sigth (Yes at Step S103), the signal processor 44 determines that the object to be detected F is not present in the object detectable space on/above the detection region AA. If the signal value Signal of each electrode 12 acquired at Step S102 is larger than the adjustment coefficient setting threshold Sigth (No at Step S103), the signal processor 44 determines that the object to be detected F is present in the object detectable space on/above the detection region AA.

If the signal value Signal of each electrode 12 acquired at Step S102 is larger than the adjustment coefficient setting threshold Sigth (No at Step S103), in other words, if it is determined that the object to be detected F is present in the object detectable space on/above the detection region AA, the signal processor 44 repeatedly performs the processing at Step S102 and Step S103.

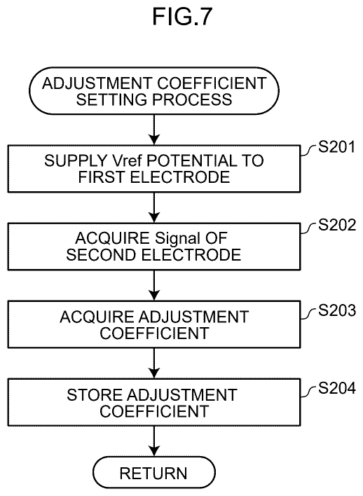

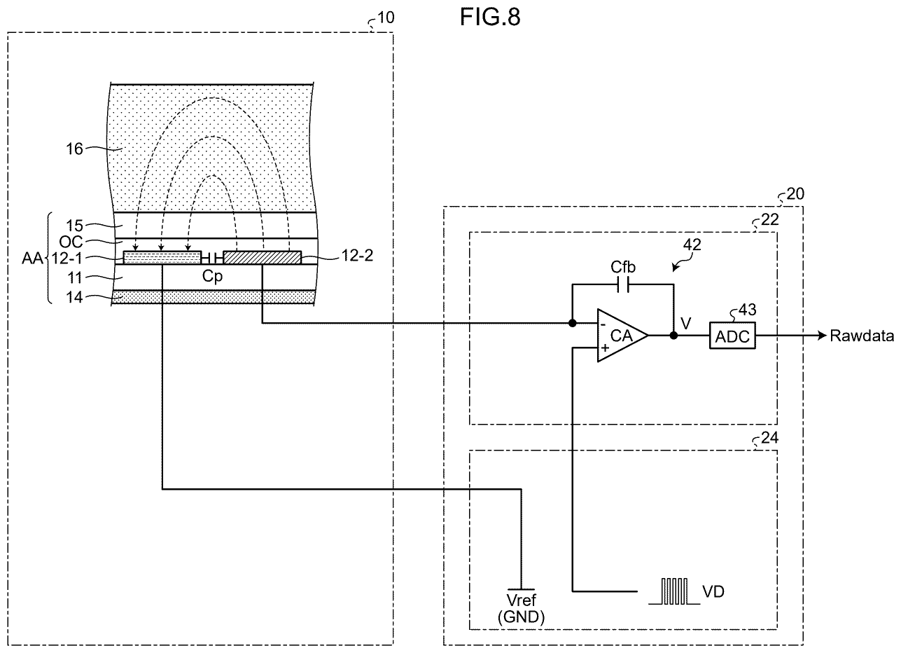

If the signal value Signal of each electrode 12 acquired at Step S102 is equal to or smaller than the adjustment coefficient setting threshold Sigth (Yes at Step S103), in other words, if it is determined that the object to be detected F is not present in the object detectable space on/above the detection region AA, the detector 20 resets an adjustment coefficient setting process execution timer T (T=0, Step S104) and performs the adjustment coefficient setting process (Step S200). FIG. 7 is a sub-flowchart of an example of the adjustment coefficient setting process in the detection device according to the first embodiment. FIG. 8 is a conceptual diagram illustrating an adjustment coefficient setting operation of the detection device according to the first embodiment.

When the system control proceeds to the adjustment coefficient setting process illustrated in FIG. 7, a reference potential Vref is supplied from the power supply circuit 24 to an electrode 12-1 (hereinafter also referred to as a “first electrode 12-1”), which is included in the electrodes 12 in the detection region AA, as illustrated in FIG. 8 (Step S201). As a result, the potential of the first electrode 12-1 is fixed at the reference potential Vref. The reference potential Vref is a GND potential, for example.

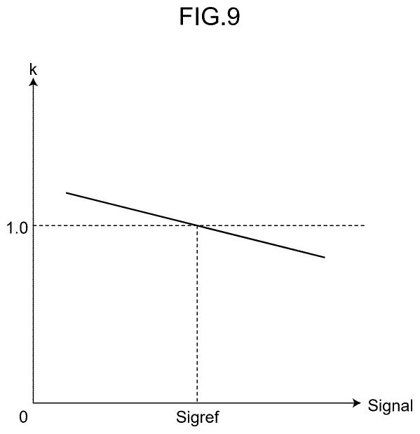

In this state, that is, when the potential of the first electrode 12-1 is fixed at the reference potential Vref (Step S201), the signal processor 44 acquires the signal value Signal of an electrode 12-2 (hereinafter also referred to as a “second electrode 12-2”) other than the first electrode 12-1 of the electrodes 12 in the detection region AA (Step S202). The signal processor 44 acquires an adjustment coefficient k using the correspondence between the signal value Signal acquired in the adjustment coefficient setting operation and the adjustment coefficient k corresponding to the moisture content of the front surface covering member 16 in the aspect illustrated in FIG. 9 (Step S203) and then stores the acquired adjustment coefficient k in the storage 46 (Step S204). The system control returns to the process illustrated in FIG. 6.

FIG. 9 is a graph indicating an example of the correspondence between the signal value acquired in the adjustment coefficient setting operation and the adjustment coefficient corresponding to the moisture content of the front surface covering member. In the present disclosure, the correspondence in the aspect illustrated in FIG. 9 is stored in advance in the storage 46.

The signal value Signal acquired in the adjustment coefficient setting operation when the object to be detected F is not present in the object detectable space on/above the detection region AA correlates with the moisture content of the front surface covering member 16. Specifically, the signal value Signal is proportional to the parasitic capacitance Cp between the first electrode 12-1 and the second electrode 12-2, and the parasitic capacitance Cp between the first electrode 12-1 and the second electrode 12-2 changes depending on the moisture content of the front surface covering member 16. In the present disclosure, the adjustment coefficient k derived by the correspondence in the aspect illustrated in FIG. 9 is set such that the detection value S detected when the object to be detected F is present in the object detectable space on/above the detection region AA is substantially constant independently of the moisture content of the front surface covering member 16.

More specifically, in the present disclosure, the adjustment coefficient k=1.0 is set corresponding to a reference signal value Sigref obtained when the moisture content of the front surface covering member 16 is a predetermined value. As the moisture content of the front surface covering member 16 increases, the capacitance value of the parasitic capacitance Cp increases, and the signal value Signal acquired in detection of the object to be detected F increases. As the moisture content of the front surface covering member 16 becomes lower than the reference value, the capacitance value of the parasitic capacitance Cp decreases, and the signal value Signal acquired in detection of the object to be detected F decreases. Therefore, the adjustment coefficient k decreases monotonically with an increase in the signal value Signal acquired in the adjustment coefficient setting operation and increases monotonically with a decrease in the signal value Signal acquired in the adjustment coefficient setting operation.

FIG. 9 illustrates an example of a function indicating the correspondence between the signal value Signal acquired in the adjustment coefficient setting operation and the adjustment coefficient k corresponding to the moisture content of the front surface covering member 16. Alternatively, a table indicating the correspondence may be stored in advance in the storage 46.

Referring back to the process illustrated in FIG. 6, the signal processor 44 acquires the signal value Signal of each electrode 12 (Step S105) and performs comparison arithmetic processing between the acquired signal value Signal and the adjustment coefficient setting threshold Sigth. Specifically, the signal processor 44 determines whether the signal value Signal of each electrode 12 acquired at Step S105 is larger than the adjustment coefficient setting threshold Sigth (Step S106).

If the signal value Signal of each electrode 12 acquired at Step S105 is larger than the adjustment coefficient setting threshold Sigth (Yes at Step S106), in other words, if it is determined that the object to be detected F is present in the object detectable space on/above the detection region AA, the signal processor 44 applies the adjustment coefficient k acquired in the adjustment coefficient setting process illustrated in FIG. 7 to the signal value Signal of each electrode 12 acquired at Step S105 and performs adjustment on the signal value Signal of each electrode 12 using the following Expression (2) (Step S107). In Expression (2), S represents the detection value of each electrode 12 resulting from the adjustment.

S=Signal×k (2)

The coordinate calculator 45 of the detector 20 calculates the spatial coordinates R (Rx, Ry, Rz) indicating the position on/above the detection region AA where the object to be detected F is present in the space on/above the detection region AA illustrated in FIG. 4B, based on the detection value S of each electrode 12 generated by the signal processor 44 (Step S108).

If the signal value Signal of each electrode 12 acquired at Step S105 is equal to or smaller than the adjustment coefficient setting threshold Sigth (No at Step S106), in other words, if it is determined that the object to be detected F is not present in the object detectable space on/above the detection region AA, the detector 20 determines whether the adjustment coefficient setting process execution timer T is equal to or larger than an adjustment coefficient setting process execution threshold Tth (e.g., one hour) (Step S109).

If the adjustment coefficient setting process execution timer T is smaller than the adjustment coefficient setting process execution threshold Tth (No at Step S109), the detector 20 returns to the processing at Step S105 and repeatedly performs the processing after Step S105.

If the adjustment coefficient setting process execution timer T is equal to or larger than the adjustment coefficient setting process execution threshold Tth (Yes at Step S109), the detector 20 returns to the processing at Step S104 and repeatedly performs the processing after Step S104.

In the process performed by the detection device 1 according to the first embodiment, the detection device 1 is started first (Step S101). If it is determined that the object to be detected F is not present in the object detectable space on/above the detection region AA (Yes at Step S103), the adjustment coefficient setting process illustrated in FIG. 7 is performed (Step S200). If it is determined that the object to be detected F is not present in the object detectable space on/above the detection region AA (No at Step S106), and if the adjustment coefficient setting process execution timer T is equal to or larger than the adjustment coefficient setting process execution threshold Tth (e.g., one hour) (Yes at Step S109), the adjustment coefficient setting process illustrated in FIG. 7 is performed (Step S200).

If it is determined that the object to be detected F is present in the object detectable space on/above the detection region AA (Yes at Step S106), the adjustment coefficient k acquired in the adjustment coefficient setting process (Step S200) is applied to the acquired signal value Signal of each electrode 12, and thus the detection value S resulting from adjustment is calculated (Step S107).

This operation can suppress deterioration in detection accuracy that would be caused by a change in permittivity of the front surface covering member 16 due to a change in humidity.

### Modifications

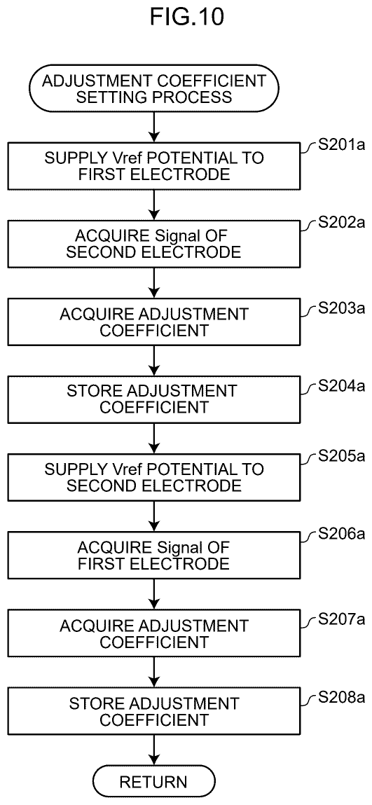

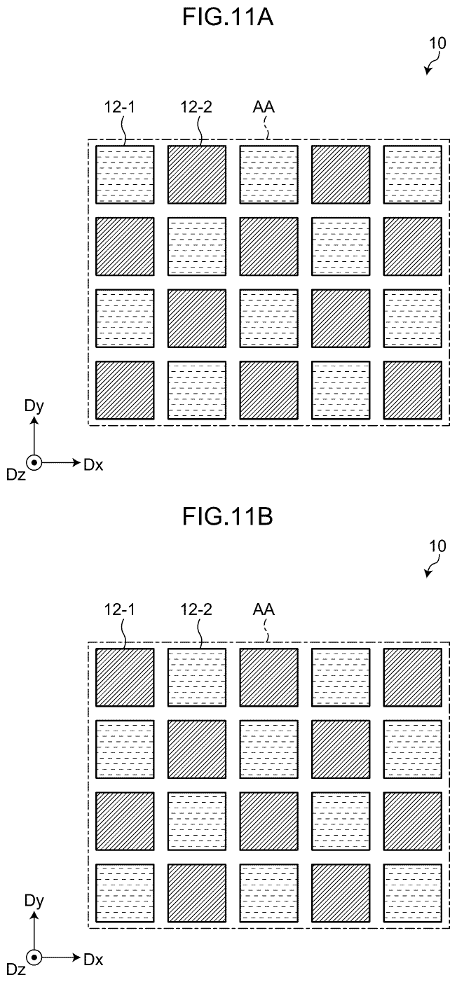

FIG. 10 is a sub-flowchart of an example of the adjustment coefficient setting process according to a modification of the first embodiment. FIGS. 11A and 11B are conceptual diagrams illustrating the adjustment coefficient setting operation according to the modification of the first embodiment.

In the adjustment coefficient setting process according to the modification of the first embodiment, as illustrated in FIG. 11A, the first electrodes 12-1 and the second electrodes 12-2 are alternately arranged in the Dx direction (first direction) and the Dy direction (second direction) in the detection region AA. In a state in which the reference potential Vref is supplied from the power supply circuit 24 to the first electrodes 12-1 (Step S201a), the signal processor 44 acquires the signal values Signal of the second electrodes 12-2 (Step S202a). The signal processor 44 acquires the adjustment coefficient k for each second electrode 12-2 individually using the correspondence between the signal value Signal acquired in the adjustment coefficient setting operation and the adjustment coefficient k corresponding to the moisture content of the front surface covering member 16 in the aspect illustrated in FIG. 9 (Step S203a) and then stores the adjustment coefficient k in the storage 46 (Step S204a).

Subsequently, as illustrated in FIG. 11B, the first electrodes 12-1 and the second electrodes 12-2 are alternately arranged in the Dx direction (first direction) and the Dy direction (second direction) in the detection region AA. In a state in which the reference potential Vref is supplied from the power supply circuit 24 to the second electrodes 12-2 (Step S205a), the signal processor 44 acquires the signal values Signal of the first electrodes 12-1 (Step S206a). The signal processor 44 acquires the adjustment coefficient k for each first electrode 12-1 individually using the correspondence between the signal value Signal acquired in the adjustment coefficient setting operation and the adjustment coefficient k corresponding to the moisture content of the front surface covering member 16 illustrated in FIG. 9 (Step S207a) and then stores the adjustment coefficient k in the storage 46 (Step S208a). The signal processor 44 returns to the process illustrated in FIG. 6.

In the detection value adjustment at Step S107 in FIG. 6, the signal processor 44 applies the adjustment coefficient k for each electrode 12 acquired in the adjustment coefficient setting process illustrated in FIG. 10 to the signal value Signal of the corresponding electrode 12 and performs adjustment on the signal value Signal of each electrode 12.

Therefore, the detection device 1 can appropriately adjust the signal value Signal of each electrode 12 if the permittivity is unevenly distributed in the detection region AA due to uneven fiber density of the front surface covering member 16 made of naturally derived wood, natural fibers, or natural leather and covering the detection region AA, for example.

### Second Embodiment

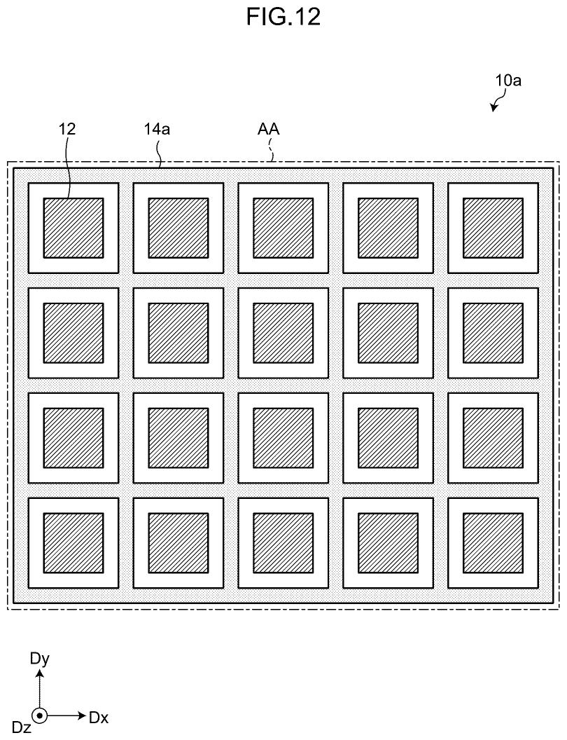

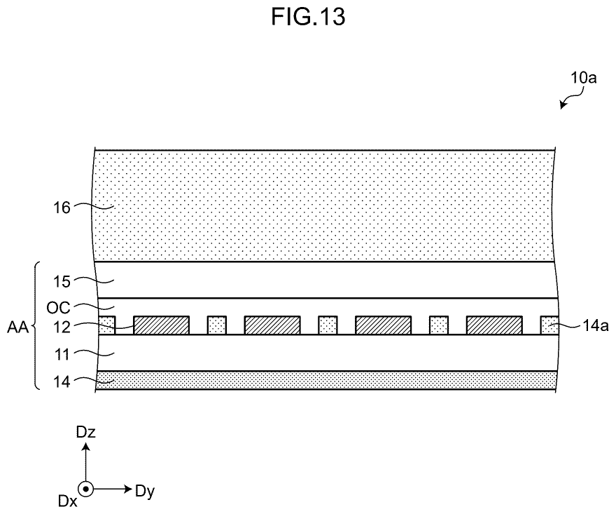

FIG. 12 is a plan view of a first example of the electrode configuration in the sensor of the detection device according to a second embodiment. FIG. 13 is a schematic of a first example of a sectional configuration of the sensor of the detection device according to the second embodiment.

In the configuration of a sensor 10a according to the first example illustrated in FIGS. 12 and 13, a plurality of electrodes 12 arranged in the Dx direction (first direction) and the Dy direction (second direction) each have four sides surrounded by a shield electrode 14a provided in a grid shape in the detection region AA. In the configuration according to the second embodiment, the shield electrode 14a is supplied with the drive signal VD from the power supply circuit 24 as in the shield electrode 14.

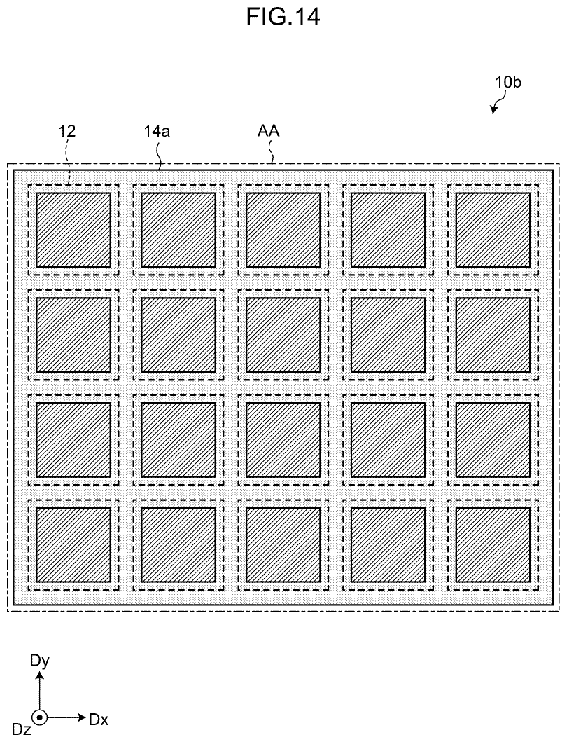

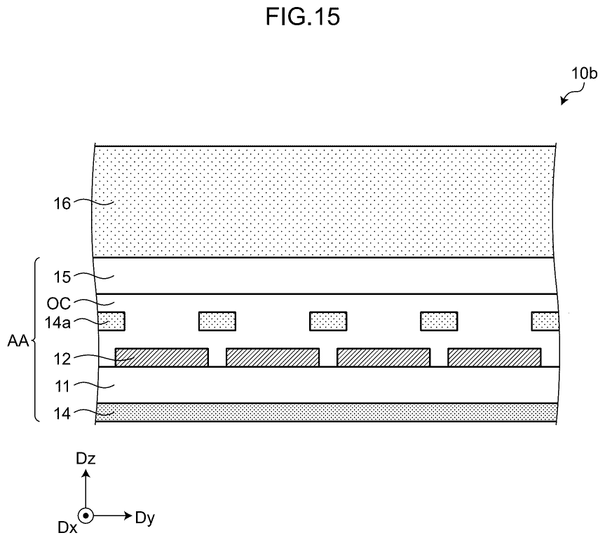

FIG. 14 is a plan view of a second example of the electrode configuration in the sensor of the detection device according to a second embodiment. FIG. 15 is a schematic of a second example of a sectional configuration of the sensor of the detection device according to the second embodiment. In the configuration of the sensor 10a according to the first example illustrated in FIGS. 12 and 13, both the electrodes 12 and the shield electrode 14a are provided on the same surface of the sensor substrate 11. By contrast, in the configuration of a sensor 10b according to the second example illustrated in FIGS. 14 and 15, the four sides of each electrode 12 overlap the shield electrode 14a when viewed in the Dz direction (third direction).

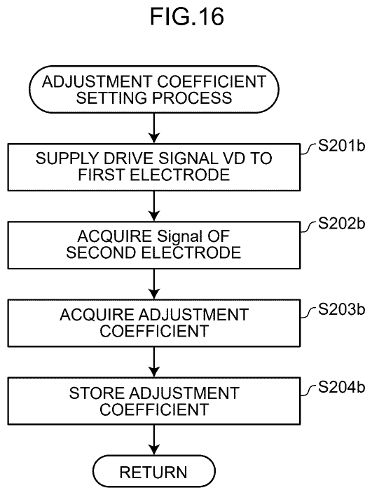

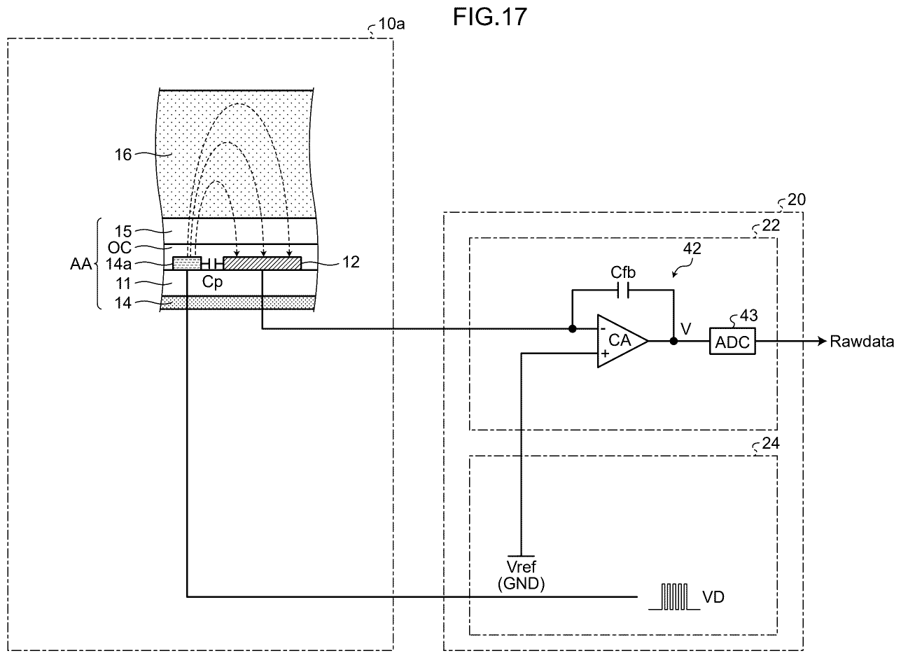

The following describes the adjustment coefficient setting operation of a detection device la according to the second embodiment with reference to the configuration of the sensor 10a according to the first example illustrated in FIGS. 12 and 13. FIG. 16 is a sub-flowchart of an example of the adjustment coefficient setting process in the detection device according to the second embodiment. FIG. 17 is a conceptual diagram illustrating the adjustment coefficient setting operation of the detection device according to the second embodiment.

In the adjustment coefficient setting process according to the second embodiment, the drive signal VD is supplied from the power supply circuit 24 to the shield electrode 14a (hereinafter also referred to as a “first electrode 14a”) as illustrated in FIG. 17 (Step S201b).

In this state, that is, when the drive signal VD is supplied to the first electrode 14a (Step S201b), the signal processor 44 acquires the signal values Signal of a plurality of electrodes 12 (hereinafter also referred to as “second electrodes 12”) (Step S202b). The signal processor 44 acquires the adjustment coefficient k for each second electrode 12 individually using the correspondence between the signal value Signal acquired in the adjustment coefficient setting operation and the adjustment coefficient k corresponding to the moisture content of the front surface covering member 16 in the aspect illustrated in FIG. 9 (Step S203b) and then stores the adjustment coefficient k in the storage 46 (Step S204b). The signal processor 44 returns to the process illustrated in FIG. 6.

In the detection value adjustment at Step S107 in FIG. 6, the signal processor 44 applies the adjustment coefficient k for each electrode 12 acquired in the adjustment coefficient setting process illustrated in FIG. 16 to the signal value Signal of the corresponding electrode 12 and performs adjustment on the signal value Signal of each electrode 12. When the signal value Signal of each electrode 12 is acquired at Step S102 and Step S105 in FIG. 6, the shield electrode 14a may be in a floating state.

Therefore, as in the modification of the first embodiment, the signal value Signal of each electrode 12 can be corrected as appropriate if the permittivity is unevenly distributed in the detection region AA due to uneven fiber density of the front surface covering member 16 made of naturally derived wood, natural fibers, or natural leather and covering the detection region AA, for example.

While exemplary embodiments according to the present disclosure have been described, the embodiments are not intended to limit the present disclosure. The contents disclosed in the embodiments are given by way of example only, and various modifications may be made without departing from the spirit of the present disclosure. Appropriate modifications made without departing from the spirit of the present disclosure naturally fall within the technical scope of the present disclosure.

What is claimed is:

1. A detection device comprising:
a detection region provided with a plurality of electrodes;
a front surface covering member made of hygroscopic non-conductive material and covering the detection region; and
a detector configured to detect an object to be detected in proximity to the detection region with the front surface covering member interposed between the object to be detected and the detection region, wherein
the detector acquires an adjustment coefficient for adjusting a signal value acquired when detecting the object to be detected, based on a correspondence between a signal value acquired in a non-detection operation in which the object to be detected is not detected and a moisture content of the front surface covering member.

2. The detection device according to claim 1, wherein the detector acquires the adjustment coefficient for each of the electrodes individually, in the non-detection operation.

3. The detection device according to claim 1, wherein the detector acquires the adjustment coefficient after the detection device is turned on.

4. The detection device according to claim 3, wherein the detector acquires the adjustment coefficient at predetermined time intervals.

5. The detection device according to claim 4, wherein the detector fixes a potential of a first electrode of the electrodes and acquires the adjustment coefficient based on a signal value of a second electrode a potential of which is not fixed, in the non-detection operation.

6. The detection device according to claim 4, wherein the detector supplies a drive signal to a first electrode of the electrodes and acquires the adjustment coefficient based on a signal value of a second electrode to which the drive signal is not supplied, in the non-detection operation.
